(19) United States
(12) Patent Application Publication
(10) Pub. No.: US 2024/0334749 A1
(43) Pub. Date: Oct. 3, 2024

(54) DISPLAY DEVICE

(71) Applicant: LG DISPLAY CO., LTD., Seoul (KR)

(72) Inventor: Jae Woo KIM, Paju-si (KR)

(73) Assignee: LG DISPLAY CO., LTD., Seoul (KR)

(21) Appl. No.: 18/605,564

(22) Filed: Mar. 14, 2024

(30) Foreign Application Priority Data
Mar. 31, 2023 (KR) 10-2023-0042743

(51) Int. Cl. H10K 59/122; H10K 59/80

(52) U.S. Cl. CPC H10K 59/122; H10K 59/873

(57) ABSTRACT

A display device includes a substrate including a display area and a non-display area around the display area, a thin film transistor disposed on the substrate, a first protective layer disposed on the thin film transistor, a second protective layer disposed on the first protective layer, a first electrode disposed on the second protective layer, a bank disposed on the first electrode, and an encapsulation portion disposed on the bank. A first stopper, a second stopper disposed adjacent to the first stopper, and a third stopper disposed adjacent to the second stopper are disposed in the non-display area, and heights of the first stopper, the second stopper, and the third stopper are different from each other.

### CROSS-REFERENCE TO RELATED APPLICATION

This application claims the priority of Korean Patent Application No. 10-2023-0042743, filed on Mar. 31, 2023, which is hereby incorporated by reference in its entirety.

### BACKGROUND

### Field of the Disclosure

The present disclosure generally relates to a display device. More specifically, the present disclosure relates to a display device capable of minimizing a non-display area located at the outskirts of the display device and controlling the overflow of an encapsulation layer.

### Description of the Background

A display device is mounted in an electronic product or a home appliance such as a television, a monitor, a laptop computer, a smartphone, a tablet computer, a portable information device, a vehicle control display device, or the like, and is used as a screen which displays images.

As such, the field of display devices, which visually display electrical information signals, is rapidly developing, and research for developing performance such as thinning, lightening, and a lower consumption strategy for various display devices is continuing.

The various display devices include a liquid crystal display (LCD) device, an organic light-emitting display (OLED) device, and the like

The organic light-emitting display device is a self-emitting display device, and does not require a separate light source, unlike a liquid crystal display device, and thus may be manufactured in a lightweight and thin form. Further, the organic light-emitting display device is not only in advantageous in terms of power consumption due to low voltage driving, but also excellent in color implementation, response time, viewing angle, and contrast ratio (CR), and thus is expected to be used in various fields.

However, since the organic light-emitting display device is vulnerable to moisture, oxygen, or the like, an encapsulation layer is formed by alternately applying organic encapsulation layers and inorganic encapsulation layers. In this case, a part of the encapsulation layer easily overflows to a periphery of a display area where an image is displayed, and in this case, the organic light-emitting display device may deteriorate due to moisture penetration from the outside. Accordingly, a problem arises in that the lifespan and reliability of the display device are lowered due to deterioration. A structure may be disposed around the display area to prevent this problem, but a phenomenon in that the encapsulation layer overflows frequently occurred.

### SUMMARY

Accordingly, the present disclosure is to provide a display device which prevents a phenomenon in that a part of an encapsulation layer overflows over a structure around a display area.

More specifically, the present disclosure is to provide a display device capable of optimizing the disposition of a structure to reduce a width of a non-display area so that a phenomenon in that a part of an encapsulation layer overflows over a structure around a display area is prevented.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a substrate including a display area and a non-display area around the display area, a thin film transistor disposed on the substrate, a first protective layer disposed on the thin film transistor, a second protective layer disposed on the first protective layer, a first electrode disposed on the second protective layer, a bank disposed on the first electrode, and an encapsulation portion disposed on the bank. A first stopper, a second stopper disposed adjacent to the first stopper, and a third stopper disposed adjacent to the second stopper are disposed in the non-display area, and heights of the first stopper, the second stopper, and the third stopper are different from each other.

In another aspect of the present disclosure, a display device includes a substrate including a display area and a non-display area including a first area around the display area, and a second area adjacent to the first area, a thin film transistor disposed on the substrate in the display area, a first protective layer disposed on the thin film transistor, a second protective layer disposed on the first protective layer, a bank disposed on the second protective layer, a first stopper located in the first area and a second stopper disposed adjacent to the first stopper, and a third stopper located in the second area and a dam disposed adjacent to the third stopper.

It is to be understood that both the foregoing general description and the following detailed description are exemplary and explanatory and are intended to provide further explanation of the disclosure as claimed.

### BRIEF DESCRIPTION OF THE DRAWINGS

The above and other features and advantages of the present disclosure will become more apparent to those of ordinary skill in the art by describing in detail exemplary aspects thereof with reference to the accompanying drawings, in which:

FIG. 1 is a view illustrating a configuration of a display device according to aspects of the present disclosure;

FIG. 2 is a cross-sectional view along line I-I′ shown in FIG. 1 according to aspects of the present disclosure;

FIG. 3 is a cross-sectional view along line II-II′ shown in FIG. 1 according to aspects of the present disclosure;

FIG. 4 is a plan view of the display device showing portion A shown in FIG. 3 according to aspects of the present disclosure;

FIG. 5 is a cross-sectional view along line II-II′ shown in FIG. 1 according to another aspect of the present disclosure;

FIG. 6 is a plan view of the display device showing portion B shown in FIG. 5 according to another aspect of the present disclosure; and

FIG. 7 is an enlarged view of the display device in which area C in FIG. 6 according to another aspect of the present disclosure is enlarged.

### DETAILED DESCRIPTION

Advantages and features of the present disclosure, and methods of achieving them will become apparent with reference to preferable aspects, which are described in detail, in conjunction with the accompanying drawings. However, the present disclosure is not limited to the aspects to be described below and may be implemented in different forms, the aspects are only provided to completely disclose the present disclosure and completely convey the scope of the present disclosure to those skilled in the art, and the present disclosure is defined by the disclosed claims.

Since the shapes, sizes, proportions, angles, numbers, and the like disclosed in the drawings for describing the aspects of the present disclosure are only exemplary, the present disclosure is not limited to the illustrated items. The same reference numerals indicate the same components throughout the disclosure. Further, in describing the present disclosure, when it is determined that a detailed description of related known technology may unnecessarily obscure the gist of the present disclosure, the detailed description thereof will be omitted. When terms such as ‘including,’ ‘having,’ ‘consisting,’ and the like mentioned in the present disclosure are used, other parts may be added unless term ‘only’ is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to,’ and the like, one or more other parts may be located between the two parts unless ‘immediately’ or ‘directly’ is used.

Although first, second, and the like are used to describe various components, these components are not limited by these terms. These terms are only used to distinguish one component from another. Accordingly, a first component, which is mentioned, below may also be a second component within the technical spirit of the present disclosure.

Features of various aspects of the present disclosure may be partially or entirely coupled or combined with each other, and technically, various linkages and operations are possible, and the aspects may be implemented independently of each other or together in a related relationship.

Hereinafter, various aspects of the present disclosure will be described in detail with reference to the accompanying drawings.

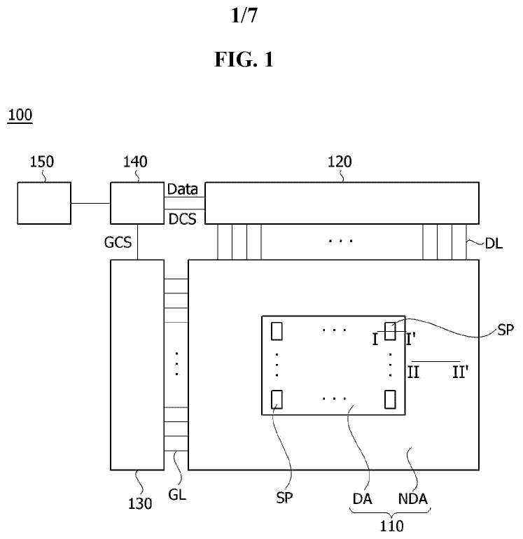

FIG. 1 is a view illustrating a configuration of a display device according to aspects of the present disclosure.

Referring to FIG. 1, a display device 100 according to aspects of the present disclosure may include a display panel 110 and a driving circuit for driving the display panel 110. The driving circuit may include a data driving circuit 120, a gate driving circuit 130, and the like. The display device 100 may further include a display controller 140 which controls the data driving circuit 120 and the gate driving circuit 130.

The display panel 110 may include signal lines such as a plurality of data lines DL and a plurality of gate lines GL, and may include a plurality of pixels to which the plurality of data lines DL and the plurality of gate lines GL are connected. Further, the pixel may include a plurality of sub-pixels SP.

The display panel 110 may include a display area DA where an image is displayed and a non-display area NDA where the image is not displayed.

In the display area DA, the signal lines such as the plurality of data lines DL and the plurality of gate lines GL may be disposed, and the plurality of sub-pixels SP for displaying an image may be disposed. The non-display area NDA may be disposed around the display area DA. The signal lines disposed in the display area DA may extend to the non-display area NDA, and in the non-display area NDA, the data driving circuit 120 and/or the gate driving circuit 130 are mounted, or a pad portion to which the data driving circuit 120, the gate driving circuit 130, a printed circuit, and the like are connected may be formed.

The data driving circuit 120 is a circuit for driving the plurality of data lines DL, and may supply data signals to the plurality of data lines DL.

The gate driving circuit 130 is a circuit for driving the plurality of gate lines GL, and may supply gate signals to the plurality of gate lines GL.

The display controller 140 may supply a data control signal DCS to the data driving circuit 120 to control an operation timing of the data driving circuit 120. The display controller 140 may supply a gate control signal GCS to the gate driving circuit 130 to control an operation timing of the gate driving circuit 130.

The display controller 140 may supply image data Data to the data driving circuit 120 on the basis of image signals input from a host module 150. For example, the display controller 140 may start scanning according to a timing implemented in each frame, convert input image data (or image signals) input from the external host module 150 to a data signal format used in the data driving circuit 120 to supply the converted image data to the data driving circuit 120, and may control data driving at an appropriate time according to scanning.

The display controller 140 receives various timing signals such as a vertical synchronization signal (VSYNC), a horizontal synchronization signal (HSYNC), an input data enable signal (DE), a clock signal (CLK), and the like together with the input image data (image signals) from the outside (for example, a host system).

To control the data driving circuit 120 and the gate driving circuit 130, the display controller 140 generates various control signals DCS and GCS and outputs the control signals DCS and GCS to the data driving circuit 120 and the gate driving circuit 130 by receiving the various timing signals such as the vertical synchronization signal (VSYNC), the horizontal synchronization signal (HSYNC), the input data enable signal (DE), the clock signal (CLK), and the like.

For example, to control the gate driving circuit 130, the display controller 140 outputs various gate control signals GCS including a gate start pulse (GSP), a gate shift clock (GSC), a gate output enable signal (GOE), and the like.

The gate start pulse (GSP) controls an operation start timing of one or more gate driver integrated circuits constituting each gate driving circuit 130. The gate shift clock (GSC) is a clock signal commonly input to one or more gate driver integrated circuits, and controls a shift timing of the scan signal (a gate pulse). The gate output enable signal (GOE) may specify timing information for one or more gate driver integrated circuits.

Further, to control the data driving circuit 120, the display controller 140 outputs various data control signals DCS including a source start pulse (SSP), a source sampling clock (SSC), a source output enable signal (SOE), and the like.

The display controller 140 may be implemented as a separate component from the data driving circuit 120, or may be integrated with the data driving circuit 120 and implemented as an integrated circuit.

The data driving circuit 120 may include one or more source driver integrated circuits (SDICs). Each source driver integrated circuit (SDIC) may include a shift register, a latch circuit, a digital to analog converter (DAC), an output buffer, and the like. In some cases, each source driver integrated circuit (SDIC) may further include an analog to digital converter (ADC).

The gate driving circuit 130 may output gate signals of a turn-on level voltage or gate signals of a turn-off level voltage according to control of the display controller 140. The gate driving circuit 130 may sequentially drive the plurality of gate lines GL by sequentially supplying the gate signals of the turn-on level voltage to the plurality of gate lines GL.

When a specific gate line GL is opened by the gate driving circuit 130, the data driving circuit 120 may convert the image data received from the display controller 140 to an analog-type data voltage and supply the analog-type data voltage to the plurality of data lines DL.

The data driving circuit 120 may be connected to one side of the display panel 110. The data driving circuit 120 may be connected to both sides of the display panel 110 or may be connected to two or more side surfaces among four side surfaces of the display panel 110 according to a driving method, a panel design method, or the like.

The display controller 140 may be a timing controller used in display technology, a control device including a timing controller and capable of further performing other control functions, or the like.

The display controller 140 may be implemented with various circuits or electronic components such as integrated circuits (ICs), field programmable gate arrays (FPGAs), application specific integrated circuits (ASICs), processors, or the like.

The display controller 140 may be mounted on a printed circuit board or flexible printed circuit board, and may be electrically connected to the data driving circuit 120 and the gate driving circuit 130 through the printed circuit board or flexible printed circuit board.

The display controller 140 may transmit and receive signals to and from the data driving circuit 120 according to one or more predetermined interfaces. For example, the interface may include a low voltage differential signaling (LVDS) interface, an embedded panel interface (EPI), a serial peripheral interface (SPI), or the like.

The display controller 140 may include storage components such as one or more registers.

The display device 100 according to the aspects of the present disclosure may be a self-emitting display such as an organic light-emitting diode (OLED) display, a quantum dot display, a micro light-emitting diode (micro-LED) display, or the like, but the aspects of the present disclosure are not limited thereto.

When the display device 100 is an OLED display, each sub-pixel SP may include an organic light-emitting diode (OLED) which emits light by itself as a light-emitting element. When the display device 100 is a quantum dot display, each sub-pixel SP may include a light-emitting element made of a quantum dot which is a semiconductor crystal which emits light by itself. When the display device 100 is a micro-LED display, each sub-pixel SP may include a micro light-emitting diode (a micro-LED) which emits light by itself as a light-emitting element and is made of an inorganic material.

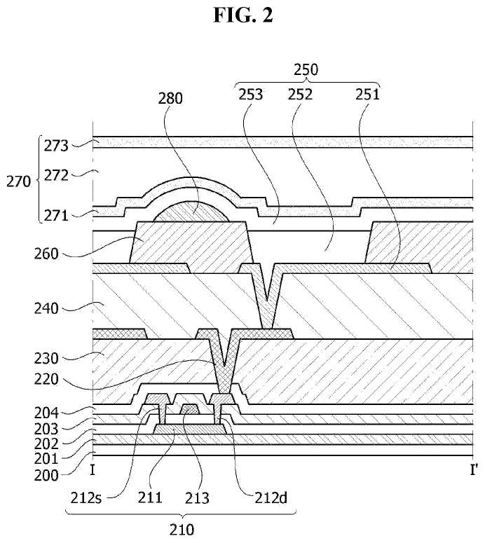

FIG. 2 is a cross-sectional view along line I-I′ shown in FIG. 1 according to the aspect of the present disclosure.

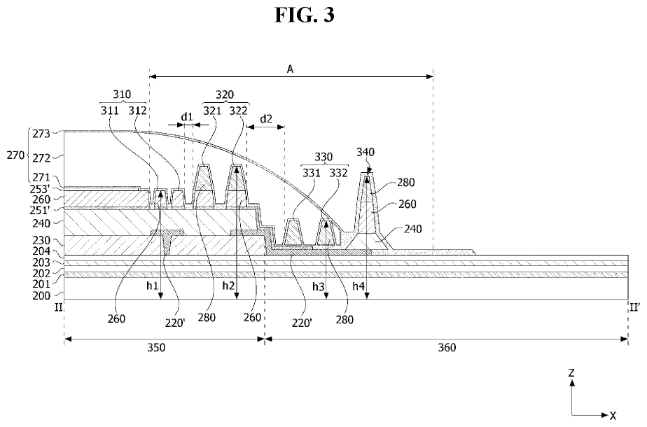

FIG. 3 is a cross-sectional view along line II-II′ shown in FIG. 1 according to the aspect of the present disclosure.

Referring to FIGS. 2 and 3, the display device 100 includes a substrate 200, a bank 260, and an encapsulation portion 270.

The substrate 200 may include a display area DA and a non-display area NDA around the display area DA. The substrate 200 may be formed throughout the display area DA and the non-display area NDA extending from the display area DA, and serves to support and protect components of the display device 100 disposed thereon. The substrate 200 may be formed of glass, and may be formed of a material having flexibility such as polyimide, but the aspects of the present disclosure are not limited thereto. The substrate 200 may be formed as a plurality of substrates 200, and insulating layers may be formed between the plurality of substrates 200.

A buffer layer 201 may be formed on the substrate 200 to protect various components of the display device 100 from penetration of moisture, hydrogen, and the like from the outside of the substrate 200. The buffer layer 201 may serve to improve an adhesive force between layers formed on the buffer layer 201 and the substrate 200, and block various types of defects such as an alkaline component and the like leaking from the substrate 200. The buffer layer 201 may prevent or delay the diffusion of moisture or oxygen which has penetrated into the substrate 200.

The buffer layer 201 may be formed of silicon oxide (SiOₓ), silicon nitride (SiNₓ), silicon oxynitride (SiNₓOₓ), or the like, but aspects of the present disclosure are not limited thereto.

A thin film transistor 210 including an active layer 211, a gate electrode 213, a source electrode 212s, and a drain electrode 212d may be disposed on the buffer layer 201.

Although only a driving thin film transistor among various thin film transistors, which may be included in the display device 100, is shown in the present disclosure, other thin film transistors such as a switching thin film transistor and the like may also be included in the display device 100.

The active layer 211 may be disposed on the buffer layer 201. The active layer 211 may be composed of amorphous silicon, polycrystalline silicon (having better mobility than amorphous silicon and having lower energy consumption and excellent reliability, and thus be capable of being applied to the driving thin film transistor within the pixel), or an oxide semiconductor such as zinc oxide (ZnO) and indium-gallium-zinc oxide (IGZO) having excellent mobility and uniformity characteristics, but is not limited thereto. When the active layer 211 is formed of an oxide semiconductor, since an effect of blocking leakage currents is excellent, changes in luminance of the sub-pixel SP may be minimized during low-speed driving.

A first insulating layer 202 may be disposed on the active layer 211. The first insulating layer 202 may insulate the active layer 211 and the gate electrode 213. The first insulating layer 202 may be formed of an insulating inorganic material such as silicon oxide (SiOₓ), silicon nitride (SiNₓ), silicon oxynitride (SiNₓOₓ), or the like, and in addition, may also be formed of an insulating organic material or the like, but is not limited thereto.

The gate electrode 213 may be disposed on the first insulating layer 202. The gate electrode 213 may be disposed to overlap the active layer 211.

The gate electrode 213 may be formed as a single layer or multiple layers formed of one of molybdenum (Mo), copper (Cu), titanium (Ti), aluminum (Al), chromium (Cr), gold (Au), nickel (Ni), neodymium (Nd), and tungsten (W) or an alloy thereof, but is not limited thereto.

A second insulating layer 203 may be disposed on the gate electrode 213. The second insulating layer 203 may be formed of an insulating inorganic material such as silicon oxide (SiOₓ), silicon nitride (SiNₓ), silicon oxynitride (SiNₓOₓ), or the like, and in addition, may also be formed of an insulating organic material or the like, but is not limited thereto.

The source electrode 212s and the drain electrode 212d may be disposed on the second insulating layer 203. The source electrode 212s and the drain electrode 212d may be electrically connected to the active layer 211 by passing through the first insulating layer 202 and the second insulating layer 203.

The source electrode 212s and the drain electrode 212d may be formed as single layers or multiple layers formed of any one of molybdenum (Mo), copper (Cu), titanium (Ti), aluminum (Al), chromium (Cr), gold (Au), nickel (Ni), and neodymium (Nd), or an alloy thereof, but are not limited thereto. For example, the source electrode 212s and the drain electrode 212d may be formed in a three-layer structure of titanium (Ti)/aluminum (Al)/titanium (Ti) formed of conductive metals, but are not limited thereto.

A third insulating layer 204 may be formed on the thin film transistor 210. The third insulating layer 204 may protect the thin film transistor 210. The third insulating layer 204 may be formed of an insulating inorganic material such as silicon oxide (SiOₓ), silicon nitride (SiNₓ), silicon oxynitride (SiNₓOₓ), or the like, and in addition, may also be formed of an insulating organic material or the like, but is not limited thereto.

A first protective layer 230 may be formed on the third insulating layer 204. The first protective layer 230 may be formed of at least one or more materials among organic insulating materials such as an acryl resin, an epoxy resin, a phenolic resin, a polyamide resin, and a polyimide resin, but is not limited thereto. For example, the first protective layer 230 may be a planarization layer or an insulating layer, but the aspects of the present disclosure are not limited thereto. A connection electrode 220 may be formed on the first protective layer 230. The connection electrode 220 may electrically connect a light-emitting portion 250 and the thin film transistor 210. The connection electrode 220 may be electrically connected to the thin film transistor 210 by passing through the third insulating layer 204 and the first protective layer 230. For example, the connection electrode 220 may be electrically connected to the drain electrode 212d of the thin film transistor 210 by passing through the third insulating layer 204 and the first protective layer 230.

A second protective layer 240 may be formed on the first protective layer 230. The connection electrode 220 may be formed between the first protective layer 230 and the second protective layer 240.

The second protective layer 240 may be formed of at least one or more materials among organic insulating materials such as an acryl resin, an epoxy resin, a phenolic resin, a polyamide resin, and a polyimide resin, but is not limited thereto. For example, the second protective layer 240 may be a planarization layer or an insulating layer, but the aspects of the present disclosure are not limited thereto.

When the first protective layer 230 and the second protective layer 240 are formed of a dielectric material, capacitance may be formed between the metal layers.

The light-emitting portion 250 including an anode electrode 251, a light-emitting layer 252, and a cathode electrode 253 may be disposed on the second protective layer 240.

The anode electrode 251 may be disposed on the second protective layer 240.

The anode electrode 251 supplies holes to the light-emitting layer 252 and may be formed of a conductive material having a high work function.

When the display device 100 is a top emission type, the anode electrode 251 is a reflective electrode, which reflects light, and may be formed of an opaque conductive material. The anode electrode 251 may be formed of at least one of silver (Ag), aluminum (Al), gold (Au), molybdenum (Mo), tungsten (W), chromium (Cr), or an alloy thereof, and may be formed in a three-layer structure of silver (Ag)/palladium (Pd)/copper (Cu), but is not limited thereto.

When the display device 100 is a bottom emission type, the anode electrode 251 may be formed of a transparent conductive material. The anode electrode 251 may be formed of at least one or more among indium tin oxide (ITO) and indium zinc oxide (IZO), but the aspects of the present disclosure are not limited thereto.

The bank 260 may be disposed on a partial area of the anode electrode 251 and a partial area of the second protective layer 240.

The bank 260 may divide a plurality of sub-pixels SP, minimize light blurring, and prevent light mixing which occurs at various viewing angles.

The bank 260 may be disposed in an area other than a light-emitting area, and may have a bank hole which exposes the anode electrode 251.

The bank 260 may be formed of at least one or more materials among inorganic insulating materials such as silicon nitride (SiNₓ) and silicon oxide (SiOₓ) and organic insulating materials such as an acryl resin, an epoxy resin, a phenolic resin, a polyamide resin, and a polyimide resin, but is not limited thereto.

A spacer 280 may be further disposed on the bank 260. The spacer 280 may minimize damage to the display device 100 from an external shock.

The light-emitting layer 252 may be disposed on the anode electrode 251. The light-emitting layer 252 may be formed of an organic material for emitting light of a specific color. The light-emitting layer 252 may be composed of at least one or more among a red organic light-emitting layer, a green organic light-emitting layer, a blue organic light-emitting layer, and a white organic light-emitting layer. A color filter may be further disposed on the light-emitting portion 250.

The cathode electrode 253 may be disposed on the light-emitting layer 252. The cathode electrode 253 supplies electrons to the light-emitting layer 252 and may be formed of a conductive material having a low work function.

When the display device 100 is a top emission type, the cathode electrode 253 may be formed of a transparent conductive material. The cathode electrode 253 may be formed of at least one or more among indium tin oxide (ITO) and indium zinc oxide (IZO), but is not limited thereto.

When the display device 100 is a bottom emission type, the cathode electrode 253 is a reflective electrode, which reflects light, and may be formed of an opaque conductive material. The cathode electrode 253 may be formed of at least one of silver (Ag), aluminum (Al), gold (Au), molybdenum (Mo), tungsten (W), chromium (Cr), or an alloy thereof.

The encapsulation portion 270 may be disposed on the light-emitting portion 250. The encapsulation portion 270 may include a first encapsulation layer 271, a second encapsulation layer 272, and a third encapsulation layer 273, and the number of encapsulation layers does not limit the scope of the present disclosure.

The encapsulation portion 270 may block penetration of moisture or oxygen, and may be formed throughout the display area DA and non-display area NDA.

The first encapsulation layer 271 and the third encapsulation layer 273 may be formed of at least one or more inorganic materials among silicon nitride (SiNₓ), silicon oxide (SiOₓ), and aluminum oxide (Al_{y}O_{z}), but the aspects of the present disclosure are not limited thereto.

The second encapsulation layer 272 may cover foreign substances or particles which may be generated in a manufacturing process.

The second encapsulation layer 272 may be formed of a silicon oxycarbon (SiOC_{z})-based, epoxy-based, polyimide-based, polyethylene-based polymer or the like, but is not limited thereto.

Hereinafter, a position relationship between a first stopper 310, a second stopper 320, a third stopper 330, and a dam 340 shown in FIG. 3 and configurations shown in FIGS. 2 and 3 will be described.

Referring to FIG. 3, the non-display area NDA of the display panel 110 may be divided into a first area 350 and a second area 360 adjacent to the first area 350. The first stopper 310, the second stopper 320, the third stopper 330, and the dam 340 may be disposed in the non-display area NDA.

The first area 350 may be an area of the non-display area NDA disposed adjacent to the display area DA. The first protective layer 230 and the second protective layer 240 formed to extend from the display area DA may be located in the first area 350. The second area 360 may be an area disposed adjacent to the first area 350. The first protective layer 230 and the second protective layer 240 formed to extend from the display area DA may not be located in the second area 360. For example, the non-display area NDA may be divided into the first area 350 which is an area where the first protective layer 230 and the second protective layer 240 are disposed, and the second area 360 which is an area of the non-display area NDA other than the first area 350, but is not limited thereto. The first stopper 310 and the second stopper 320 may be disposed in the first area 350 of the non-display area NDA, and the third stopper 330 may be disposed in the second area 360. For example, the second stopper 320 may be disposed adjacent to the first stopper 310. The third stopper 330 may be disposed adjacent to the second stopper 320.

The dam 340 may be further disposed in the second area 360. When the dam 340 is disposed in the display device 100, the dam 340 may be disposed as one. That is, it is possible to only provide one dam 340. Accordingly, the non-display area NDA located at the outskirts of the display device 100 may be minimized. The dam 340 may be disposed adjacent to the third stopper 330.

The first stopper 310, the second stopper 320, the third stopper 330, and the dam 340 may prevent defects from being generated in the display device 100 due to the second encapsulation layer 272 overflowing the dam 340. For example, the first stopper 310, the second stopper 320, and the third stopper 330 may be a first structure, a second structure, and a third structure respectively, but the aspects of the present disclosure are not limited thereto. A first electrode 251′ may be formed on the second protective layer 240. The first electrode 251′ may be formed on the same layer and made of the same material as the anode electrode 251 shown in FIG. 2, but the aspects of the present disclosure are not limited thereto.

The first electrode 251′ may be formed to extend into the first area 350 and the second area 360. For example, the first electrode 251′ may be formed throughout the first area 350 and the second area 360. The first electrode 251′ may be formed to overlap the first stopper 310 and the second stopper 320. The first electrode 251′ may be formed on one side of the first protective layer 230 and the second protective layer 240 formed in the first area 350. The first electrode 251′ may overlap a portion of the third stopper 330 disposed in the second area 360.

A first metal layer 220′ may be formed between the first protective layer 230 and the second protective layer 240. The first metal layer 220′ may be formed on the same layer as the connection electrode 220. The first metal layer 220′ may overlap portions of the first stopper 310 and the second stopper 320. The first metal layer 220′ may be formed to extend into the first area 350 and the second area 360, and may overlap portions of the third stopper 330 and the dam 340. For example, the first metal layer 220′ may be formed throughout the first area 350 and the second area 360.

The encapsulation portion 270 may overlap the first stopper 310 and the second stopper 320. For example, the encapsulation portion 270 may be formed on the first stopper 310 and the second stopper 320. According to the aspect of the present disclosure, as the first stopper 310 and the second stopper 320 are formed, an amount of the second encapsulation layer 272 which overflows the dam 340 disposed at the outermost side of the non-display area NDA may be minimized.

The spacer 280 may be further formed on the bank 260. The spacer 280 may minimize the damage to the display device 100 from an external shock by buffering an empty space between the substrate 200 on which the light-emitting portion 250 is formed and an upper substrate. The spacer 280 may be formed of the same material as the bank 260, but the aspects of the present disclosure are not limited thereto. The spacer 280 may be simultaneously formed with the bank 260, but the aspects of the present disclosure are not limited thereto.

According to the aspect of the present disclosure, at least one or more of the first stopper 310 and the second stopper 320 in the first area 350 may be composed of a different layer from the third stopper 330 in the second area 360. For example, the first stopper 310 may include the bank 260. For example, the second stopper 320 may include the bank 260 and the spacer 280. For example, the third stopper 330 may include the spacer 280.

According to the aspect of the present disclosure, the first stopper 310, the second stopper 320, the third stopper 330, and the dam 340 may include the same layer as portions of the bank 260, the spacer 280, and the second protective layer 240. For example, the first stopper 310 may include the bank 260. For example, the second stopper 320 may include the bank 260 and the spacer 280. For example, the third stopper 330 may include the spacer 280. For example, the dam 340 may include the second protective layer 240, the bank 260, and the spacer 280.

Each of the first stopper 310, the second stopper 320, and the third stopper 330 may include a plurality of sub-stoppers disposed to be spaced apart from each other.

For example, the first stopper 310 may include a first-a sub-stopper 311 and a first-b sub-stopper 312. For example, the first metal layer 220′ may overlap the first-a sub-stopper 311 and the first-b sub-stopper 312. For example, the first electrode 251′ may be formed to overlap the first-a sub-stopper 311 and the first-b sub-stopper 312.

The second stopper 320 may include a second-a sub-stopper 321 and a second-b sub-stopper 322. For example, the first metal layer 220′ may overlap the second-b sub-stopper 322. For example, the first electrode 251′ may be formed to overlap the second-a sub-stopper 321 and the second-b sub-stopper 322.

The third stopper 330 may include a third-a sub-stopper 331 and a third-b sub-stopper 332. For example, the first metal layer 220′ may overlap the third-a sub-stopper 331 and the third-b sub-stopper 332. For example, the first metal layer 220′ may overlap the second-b sub-stopper 322, the third-a sub-stopper 331, and the third-b sub-stopper 332. For example, the first metal layer 220′ may overlap the second-b sub-stopper 322, the third-a sub-stopper 331, the third-b sub-stopper 332, and the dam 340. The first metal layer 220′ may be formed to extend from the second-b sub-stopper 322 to the dam 340. For example, the first metal layer 220′ may be formed to extend from the second-b sub-stopper 322 to a portion of the dam 340. For example, the first electrode 251′ may be formed to overlap the third-a sub-stopper 331. The first electrode 251′ may be formed to overlap the third-a sub-stopper 331 to a middle of the third-a sub-stopper 331 and the third-b sub-stopper 332. For example, the first electrode 251′ may be formed to extend from the second-b sub-stopper 322 to the middle of the third-a sub-stopper 331 and the third-b sub-stopper 332.

For example, each of the first stopper 310, the second stopper 320, and the third stopper 330 has two sub-stoppers, but is not necessarily limited thereto. For example, each of the first stopper 310, the second stopper 320, and the third stopper 330 has two or more sub-stoppers. Even, the first stopper 310, the second stopper 320, and the third stopper 330 may have different number of sub-stoppers from each other, or the same number of sub-stoppers.

As each of the first stopper 310, the second stopper 320, and the third stopper 330 has two or more sub-stoppers, an amount of the second encapsulation layer 272 overflowing the dam 340 may be minimized.

The first stopper 310 may include the bank 260, the second stopper 320 may include the bank 260 and the spacer 280, the third stopper 330 may include the spacer 280, and the dam 340 may include the second protective layer 240, the bank 260, and the spacer 280, but are not limited to.

A direction parallel to the substrate 200, and in which the first stopper 310, the second stopper 320, the third stopper 330, and the dam 340 are disposed may be a first direction (an X direction), and the first stopper 310, the second stopper 320, the third stopper 330, and the dam 340 may be disposed to be spaced apart from each other in the first direction (the X direction) parallel to the substrate 200.

The closest distance in the first direction (the X direction) between portions of the first stopper 310 and the second stopper 320 extending in a third direction (a Z direction) perpendicular to the substrate 200 may be a first distance d1. Further, the closest distance between portions of the second stopper 320 and the third stopper 330 extending in the third direction (the Z direction) may be a second distance d2. As shown in FIG. 3, a separation distance between the first stopper 310 and the second stopper 320 disposed adjacent to each other in the first direction (the X direction) may be the first distance d1. Further, a separation distance between the second stopper 320 and the third stopper 330 disposed adjacent to each other in the first direction may be the second distance d2.

The first distance d1 may be a separation distance between the first stopper 310 and the second stopper 320, and the second distance d2 may be a separation distance between the second stopper 320 and the third stopper 330.

The second distance d2 may be greater than the first distance d1. For example, the separation distance between the second stopper 320 and the third stopper 330 may be greater than the separation distance between the first stopper 310 and the second stopper 320. Further, a separation distance between the two second stoppers 320 in the first direction may be greater than the first distance d1. In addition, the separation distance between the two third stoppers 330 in the first direction may be smaller than the second distance d2.

Distances from a lower surface of the substrate 200 to the tops of the first stopper 310, the second stopper 320, the third stopper 330, and the dam 340 in the third direction (the Z direction) may be respectively referred as a first height h1, a second height h2, a third height h3, and a fourth height h4.

The first height h1, the second height h2, the third height h3, and the fourth height h4 may be different from each other. The second height h2 may be greater than the first height h1, and the first height h1 may be greater than the third height h3. Since the heights of the first stopper 310, the second stopper 320, the third stopper 330, and the dam 340 from the lower surface of the substrate 200 are configured differently, the second encapsulation layer 272 may be effectively controlled.

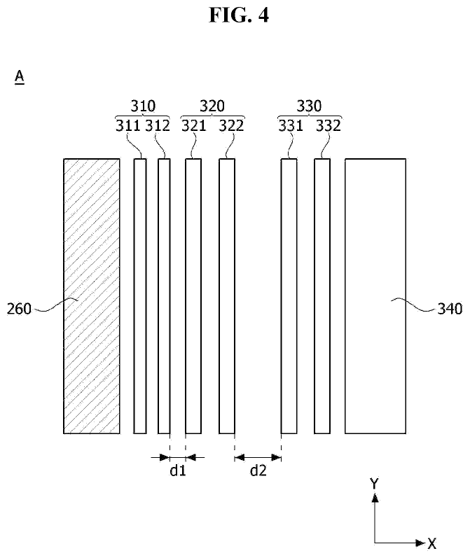

FIG. 4 is a plan view of the display device showing portion A shown in FIG. 3 according to the aspect of the present disclosure.

Referring to FIG. 4, the bank 260 and the first stopper 310 may not be connected. For example, the bank 260 and the first stopper 310 may be disposed to be spaced apart from each other. The first stopper 310, the second stopper 320, the third stopper 330, and the dam 340 may be formed in a second direction (a Y direction) different from the first direction (the X direction). Here, the first direction and the second direction may be disposed on a horizontal plane, and the first direction (the X direction) and the second direction (the Y direction) may be perpendicular to each other.

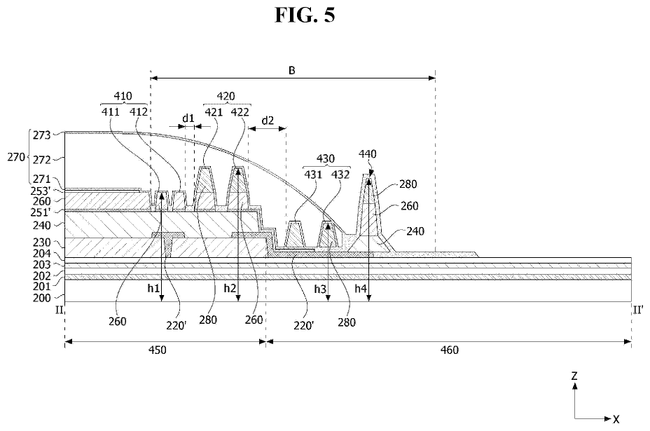

FIG. 5 is a cross-sectional view along line II-II′ shown in FIG. 1 according to another aspect of the present disclosure.

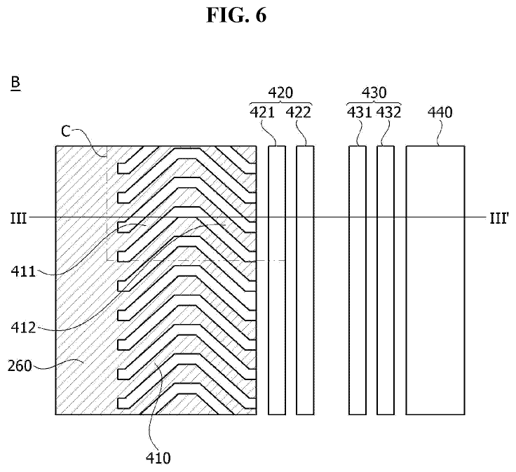

FIG. 6 is a plan view of the display device showing portion B shown in FIG. 5 according to another aspect of the present disclosure.

Hereinafter, in the case of FIGS. 5 and 6, content substantially the same as that in FIGS. 3 and 4 will be omitted, and different portions will be mainly described.

Referring to FIGS. 5 and 6, the non-display area NDA may include a first area 450 and a second area 460 adjacent to the first area 450.

A first protective layer 230 and a second protective layer 240 may be formed in the first area 450. A first stopper 410 and a second stopper 420 may be formed on the second protective layer 240.

As shown in FIG. 6, the first stopper 410 may be connected to a bank 260. The first stopper 410 may be one pattern in the bank 260, and one surface patterned in the bank 260 may represent the first stopper 410. As shown in FIG. 5, a first portion 411 of the first stopper and a second portion 412 of the first stopper are portions of the first stopper 410, and may be connected to each other. For example, FIG. 5 may be a cross-sectional view along line III-III′ shown in FIG. 6. As shown in FIG. 6, a plurality of first stoppers 410 may be disposed to be spaced apart from each other along the second direction.

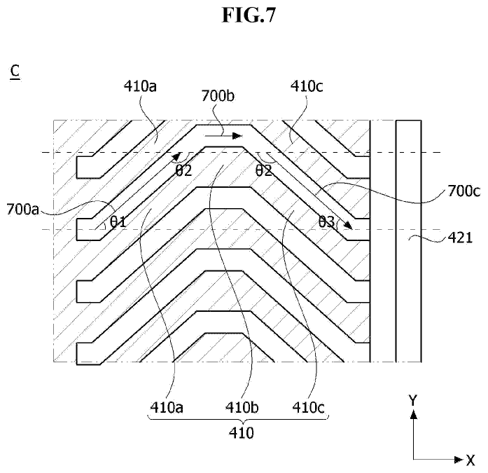

FIG. 7 is an enlarged view of the display device in which area C in FIG. 6 according to another aspect of the present disclosure is enlarged.

Referring to FIG. 7, the first stopper 410 connected to the bank 260 may be divided into a first portion 410a, a second portion 410b, and a third portion 410c. A connection portion for connecting the first stopper 410 and the bank 260 may be disposed between the first stopper 410 and the bank 260.

The first portion 410a of the first stopper 410 may be located closer to the bank 260 than the second portion 410b and the third portion 410c, and a pattern formed of the same material as the bank 260 in the first portion 410a may be formed in a direction 700a different from the first direction (the X direction). The second portion 410b of the first stopper 410 may be located between the first portion 410a and the third portion 410c, and a pattern formed of the same material as the bank 260 in the second portion 410b may be formed in the same direction 700b as the first direction (the X direction). The third portion 410c of the first stopper 410 may be located adjacent to a portion of the second stopper 420, and the pattern formed of the same material as the bank 260 in the third portion 410c may be formed in a direction 700c different from the first direction (the X direction). For example, the first portion 410a extending from one side of the bank 260 may be formed to have a predetermined first inclination angle θ1 with respect to the first direction. For example, the first inclination angle θ1 may be an acute angle. Further, the second portion 410b may extend from an end portion of the first portion 410a in a direction the same as the first direction. For example, the second portion 410b may be formed to have a predetermined second inclination angle θ2 with respect to the first portion 410a, and the second inclination angle θ2 may be an obtuse angle. Further, the third portion 410c may extend from an end portion of the second portion 410b. For example, the third portion 410c may be formed to have the second inclination angle θ2 with respect to the second portion 410b, and may be formed to have a predetermined third inclination angle θ3 with respect to the first direction, and the third inclination angle θ3 may be an acute angle. Sizes of the first inclination angle θ1 and the third inclination angle θ3 may be the same, but are not necessarily limited thereto, and the first and third inclination angles may be acute angles. Further, the direction indicated by the reference numeral 700a may be a fourth direction and may represent a direction parallel to an inclined surface of the first portion 410a. In addition, the direction indicated by the reference numeral 700b may be a fifth direction (the same as the first direction) and may represent a direction parallel to a side surface of the second portion 410b. In addition, the direction indicated by the reference numeral 700c may be a sixth direction and may represent a direction parallel to an inclined surface of the third portion 410c. For example, the first portion 410a may be located closer to the bank 260 than the second portion 410b and the third portion 410c, the second portion 410b may be located adjacent to the first portion 410a, and the third portion 410c may be located adjacent to the second portion 410b.

The first portion 410a and the third portion 410c are respectively formed in the directions 700a and 700c different from the first direction (the X direction), and the directions 700a and 700c of the first portion 410a and the third portion 410c different from the first direction (the X direction) respectively have first angles θ1 and θ3 with respect to the first direction (the X direction). For example, the first portion 410a and the third portion 410c have the first angles θ1 and θ3 with respect to the first direction (the X direction).

The first portion 410a and the third portion 410c may be line symmetrical with respect to the second portion 410b.

As the first portion 410a and the third portion 410c of the first stopper 410 have the first angles θ1 and θ3 with respect to the first direction (the X direction), the direction 700b in which the second portion 410b is formed has a second angle θ2 with respect to the directions 700a and 700c different from the first direction (the X direction).

The first angles θ1 and θ3 may be different from the second angle θ2. As the first angles θ1 and θ3 are angles different from the second angle θ2, the overflow of the second encapsulation layer 272 may be minimized. For example, since the angle formed by the first portion 410a with respect to the first direction (the X direction) and the angle formed by the first portion 410a and the second portion 410b are configured differently, the overflow of the second encapsulation layer 272 may be minimized.

The first portion 410a and the second portion 410b may be formed to have different angles with respect to the first direction (the X direction).

Accordingly, since the plurality of first stoppers 410 are formed to be spaced apart from each other in the second direction (the Y direction), a space through which materials constituting the encapsulation layers may flow may be formed between the plurality of first stoppers 410. Further, a size of the space may increase due to the angles formed by the first portion 410a, the second portion 410b, and the third portion 410c. Accordingly, since more of the materials constituting the encapsulation layers may be filled in the space, an amount of the second encapsulation layer 272 overflowing the dam 340 may also be minimized.

The display device according to the aspect of the present disclosure may be described as follows.

A display device according to an aspect of the present disclosure may include a substrate including a display area and a non-display area disposed around the display area, a thin film transistor disposed on the substrate, a first protective layer disposed on the thin film transistor, a second protective layer disposed on the first protective layer, a first electrode disposed on the second protective layer, a bank disposed on the first electrode, and an encapsulation portion disposed on the bank. A first stopper, a second stopper disposed adjacent to the first stopper, and a third stopper disposed adjacent to the second stopper may be disposed in the non-display area, and heights of the first stopper, the second stopper, and the third stopper may be different from each other.

According to one or more aspects of the present disclosure, the non-display area may include a first area disposed around the display area, and a second area adjacent to the first area, the first stopper and the second stopper may be disposed in the first area, and the third stopper may be disposed in the second area.

According to one or more aspects of the present disclosure, the encapsulation portion may overlap with the first stopper and the second stopper.

According to one or more aspects of the present disclosure, the first electrode may overlap with the first stopper and the second stopper.

According to one or more aspects of the present disclosure, the display device may further include a dam in the second area.

According to one or more aspects of the present disclosure, the dam may be configured as one.

According to one or more aspects of the present disclosure, the first stopper may be connected to the bank.

According to one or more aspects of the present disclosure, a separation distance between the second stopper and the third stopper may be greater than a separation distance between the first stopper and the second stopper.

According to one or more aspects of the present disclosure, the display device may further include a first metal layer between the first protective layer and the second protective layer, wherein the first metal layer may overlap with portions of the first stopper and the second stopper.

According to one or more aspects of the present disclosure, the display device may further include a spacer disposed on the bank, wherein the second stopper may include the same material as the spacer, and may be formed of multiple layers.

According to one or more aspects of the present disclosure, the first stopper may include a first portion, a second portion disposed adjacent to the first portion, and a third portion disposed adjacent to the second portion, the first portion may connect the bank with the second portion, and the second portion may be disposed between the first portion and the third portion.

According to one or more aspects of the present disclosure, the first portion and the second portion of the first stopper may have different angles with respect to a first direction.

A display device according to an aspect of the present disclosure may include a substrate including a display area and a non-display area including a first area disposed around the display area, and a second area adjacent to the first area, a thin film transistor disposed on the substrate in the display area, a first protective layer disposed on the thin film transistor, a second protective layer disposed on the first protective layer, a bank disposed on the second protective layer, a first stopper disposed in the first area and a second stopper disposed adjacent to the first stopper, and a third stopper disposed in the second area and a dam disposed adjacent to the third stopper.

According to one or more aspects of the present disclosure, the display device may further include an encapsulation portion disposed on the bank, wherein the encapsulation portion may overlap with the first stopper and the second stopper.

According to one or more aspects of the present disclosure, the display device may further include a first electrode disposed on the second protective layer, wherein the first electrode may overlap with the first stopper and the second stopper.

According to one or more aspects of the present disclosure, a separation distance between the second stopper and the third stopper may be greater than a separation distance between the first stopper and the second stopper.

According to one or more aspects of the present disclosure, the first stopper may be connected to the bank.

According to one or more aspects of the present disclosure, the first stopper may include a first portion, a second portion disposed adjacent to the first portion, and a third portion disposed adjacent to the second portion, the first portion may connect the bank with the second portion, and the second portion may be disposed between the first portion and the third portion.

According to one or more aspects of the present disclosure, the first portion and the second portion of the first stopper may have different angles with respect to a first direction.

According to the present disclosure, a display device having high stability may be provided by preventing or minimizing the overflow of an encapsulation layer including an organic material over a structure in a non-display area to protect the display device.

According to the present disclosure, a display device capable of reducing a width of a non-display area may be provided by disposing a structure capable of preventing the overflow of an encapsulation layer including an organic material in the non-display area.

According to the present disclosure, since a layer forming a structure which prevents the overflow of an encapsulation layer including an organic material and a layer formed in a display area may be simultaneously formed, a display device having a simplified process may be provided.

Effects according to the present disclosure are not limited to the content exemplified above, and more various effects are included in the present disclosure.

Although the aspects of the present disclosure have been described in more detail with reference to the accompanying drawings, the present disclosure is not limited thereto and may be embodied in many different forms without departing from the technical concept of the present disclosure. Therefore, the aspects disclosed in the present disclosure are provided for illustrative purposes only and are not intended to limit the technical concept of the present disclosure. The scope of the technical concept of the present disclosure is not limited thereto. Therefore, it should be understood that the above-described aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate including a display area and a non-display area disposed around the display area;
a thin film transistor disposed on the substrate;
a first protective layer disposed on the thin film transistor;
a second protective layer disposed on the first protective layer;
a first electrode disposed on the second protective layer;
a bank disposed on the first electrode;
an encapsulation portion disposed on the bank;
a first stopper, a second stopper disposed adjacent to the first stopper, and a third stopper disposed adjacent to the second stopper and disposed in the non-display area,
wherein heights of the first stopper, the second stopper, and the third stopper are different from one another.

2. The display device of claim 1, wherein the non-display area includes a first area around the display area, and a second area adjacent to the first area,
wherein the first stopper and the second stopper are disposed in the first area, and
wherein the third stopper is disposed in the second area.

3. The display device of claim 1, wherein the encapsulation portion overlaps the first stopper and the second stopper.

4. The display device of claim 1, wherein the first electrode overlaps the first stopper and the second stopper.

5. The display device of claim 2, further comprising a dam disposed in the second area.

6. The display device of claim 5, wherein the dam is configured as one.

7. The display device of claim 1, wherein the first stopper is connected to the bank.

8. The display device of claim 1, wherein a separation distance between the second stopper and the third stopper is greater than a separation distance between the first stopper and the second stopper.

9. The display device of claim 1, further comprising a first metal layer disposed between the first protective layer and the second protective layer,
wherein the first metal layer overlaps portions of the first stopper and the second stopper.

10. The display device of claim 1, further comprising a spacer disposed on the bank,
wherein the second stopper includes the same material as the spacer, and is formed of multiple layers.

11. The display device of claim 1, wherein the first stopper includes a first portion, a second portion located adjacent to the first portion, and a third portion located adjacent to the second portion,
wherein the first portion connects the bank and the second portion, and
wherein the second portion is disposed between the first portion and the third portion.

12. The display device of claim 11, wherein the first portion and the second portion of the first stopper have different angles with respect to a first direction.

13. The display device of claim 1, wherein each of the first stopper, the second stopper, and the third stopper has two or more sub-stoppers.

14. A display device comprising:
a substrate including a display area and a non-display area including a first area around the display area, and a second area adjacent to the first area;
a thin film transistor disposed on the substrate in the display area;
a first protective layer disposed on the thin film transistor;
a second protective layer disposed on the first protective layer;
a bank disposed on the second protective layer;
a first stopper located in the first area and a second stopper disposed adjacent to the first stopper; and
a third stopper located in the second area and a dam disposed adjacent to the third stopper.

15. The display device of claim 14, further comprising an encapsulation portion disposed on the bank,
wherein the encapsulation portion overlaps the first stopper and the second stopper.

16. The display device of claim 14, further comprising a first electrode disposed on the second protective layer,
wherein the first electrode overlaps the first stopper and the second stopper.

17. The display device of claim 14, wherein a separation distance between the second stopper and the third stopper is greater than a separation distance between the first stopper and the second stopper.

18. The display device of claim 14, wherein the first stopper is connected to the bank.

19. The display device of claim 14, wherein the first stopper includes a first portion, a second portion located adjacent to the first portion, and a third portion located adjacent to the second portion,
wherein the first portion connects the bank and the second portion, and
wherein the second portion is disposed between the first portion and the third portion.

20. The display device of claim 19, wherein the first portion and the second portion of the first stopper have different angles with respect to a first direction.
